(19) United States
(12) Patent Application Publication
(10) Pub. No.: US 2024/0088082 A1
(43) Pub. Date: Mar. 14, 2024

(54) SEMICONDUCTOR PACKAGE

(71) Applicant: Samsung Electronics Co., Ltd., Suwon-si (KR)

(72) Inventors: Sang Ho Cha, Suwon-si (KR); Yun-Rae Cho, Suwon-si (KR)

(73) Assignee: Samsung Electronics Co., Ltd., Suwon-si (KR)

(21) Appl. No.: 18/229,446

(22) Filed: Aug. 2, 2023

(30) Foreign Application Priority Data
Sep. 8, 2022 (KR) 10-2022-0113913

(51) Int. Cl. H01L 23/00; H01L 23/522; H01L 23/544; H01L 25/065

(52) U.S. Cl. CPC H01L 24/17; H01L 23/5228; H01L 23/544; H01L 24/16; H01L 25/0657; H01L 2223/54426; H01L 2224/16146; H01L 2224/16227; H01L 2224/1703; H01L 2224/17133; H01L 2225/06513; H01L 2225/06517; H01L 2225/06544; H01L 2924/3511

(57) ABSTRACT

A semiconductor package, including a substrate extending in first direction and a second direction intersecting the first direction and including a solder resist layer having an open area thereon; a semiconductor chip on the substrate in a third direction, the third direction intersecting the first direction and the second direction, a first surface of the semiconductor chip facing the substrate; and a bump structure in contact with a first connection pad on the open area and a second connection pad on the first surface of the semiconductor chip, and configured to connect the substrate to the semiconductor chip, wherein the open area includes a first area and a second area disposed in a peripheral part of the first area, and wherein a length of the first area in the first direction is greater than a length of the second area in the first direction.

### CROSS-REFERENCE TO RELATED APPLICATION

This application claims priority to Korean Patent Application No. 10-2022-0113913, filed on Sep. 8, 2022, in the Korean Intellectual Property Office, the disclosure of which is incorporated by reference herein in its entirety.

### BACKGROUND

### 1. Field

The present disclosure relates to a semiconductor package.

### 2. Description of the Related Art

A semiconductor package may include a plurality of semiconductor chips stacked on a substrate. The substrate and the semiconductor chip may be electrically connected through a connection structure including a conductive bump and a pad.

In such a construction, warpage may occur in the semiconductor chip in the process of bonding the substrate to the semiconductor chip. Due to this warpage, a short may occur between conductive bumps disposed in a central part of the semiconductor chip and a non-wet defect may occur in the conductive bumps disposed in the periphery of the semiconductor chip.

### SUMMARY

One or more example embodiments provide a semiconductor package that improves the reliability of a conductive bump.

According to an aspect of an example embodiment, a semiconductor package, includes: a substrate extending in first direction and a second direction intersecting the first direction and comprising a solder resist layer having an open area thereon; a semiconductor chip on the substrate in a third direction, the third direction intersecting the first direction and the second direction, a first surface of the semiconductor chip facing the substrate; and a bump structure in contact with a first connection pad on the open area and a second connection pad on the first surface of the semiconductor chip, and configured to connect the substrate to the semiconductor chip, wherein the open area comprises a first area and a second area disposed in a peripheral part of the first area, and wherein a length of the first area in the first direction is greater than a length of the second area in the first direction.

According to an aspect of an example embodiment, a semiconductor package, including: a semiconductor chip; a substrate on a lower part of the semiconductor chip and extending in a first direction and a second direction intersecting the first direction, and comprising a solder resist layer having a first open area in a central part of the semiconductor chip and a second open area in a peripheral part of the semiconductor chip, when viewed in a plan view; and a bump structure connecting the substrate to the semiconductor chip, wherein the bump structure comprises: a first solder bump in contact with a first connection pad disposed on the first open area and a second connection pad disposed on a first surface of the semiconductor chip; and a second solder bump in contact with a third connection pad disposed on the second open area and a fourth connection pad disposed on the first surface of the semiconductor chip, wherein a length of the first open area in the first direction is greater than a length of the second open area in the first direction, and wherein a width of the first solder bump in the first open area in the second direction is smaller than a width of the second solder bump in the second open area in the second direction.

According to an aspect of an example embodiment, a semiconductor package, includes: a substrate extending in a first direction and a second direction intersecting the first direction and comprising a solder resist layer having an open area thereon; a first semiconductor chip disposed on the substrate and stacked vertically so that the substrate and a first surface of the first semiconductor chip face each other; an alignment pattern disposed adjacent to an edge area of the first semiconductor chip; a non-conductive material layer between the substrate and the first semiconductor chip; and a first bump structure disposed between a first connection pad on the open area and a second connection pad on the first surface of the first semiconductor chip and connecting the substrate to the first semiconductor chip, wherein the open area comprises a first area and a second area adjacent to a peripheral part of the first area, when viewed in a plan view, and wherein a length of the first area in the first direction is greater than a length of the second area in the first direction.

### BRIEF DESCRIPTION OF DRAWINGS

The above and other aspects and features will be more apparent from the following description of example embodiments, taken in conjunction with the accompanying drawings, in which:

FIG. 1 is an exemplary layout view describing a semiconductor package according to some embodiments of the present disclosure;

FIG. 2 is a sectional view taken along line I-I′ of FIG. 1;

FIG. 3 is an enlarged view describing an area P1 of FIG. 1;

FIG. 4 is an enlarged view describing an area P2 of FIG. 1;

FIG. 5A is an enlarged view describing the area P1 of FIG. 2;

FIG. 5B is an enlarged view describing the area P2 of FIG. 2;

FIG. 6 is a view describing the semiconductor package according to some embodiments of the present disclosure, which corresponds to FIG. 3;

FIG. 7 is a view describing the semiconductor package according to some embodiments of the present disclosure, which corresponds to FIG. 3;

FIG. 8 is a view describing the semiconductor package according to some embodiments of the present disclosure, which corresponds to FIG. 3;

FIG. 9 is a sectional view illustrating the semiconductor package according to some embodiments of the present disclosure;

FIG. 10 is a block diagram illustrating a memory card including the semiconductor package according to some embodiments of the present disclosure; and

FIG. 11 is a block diagram illustrating an information processing system using the semiconductor package according to some embodiments of the present disclosure.

### DETAILED DESCRIPTION

Example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. The same or similar elements are assigned the same reference numerals irrespective of their reference numerals, and a redundant description thereof is omitted.

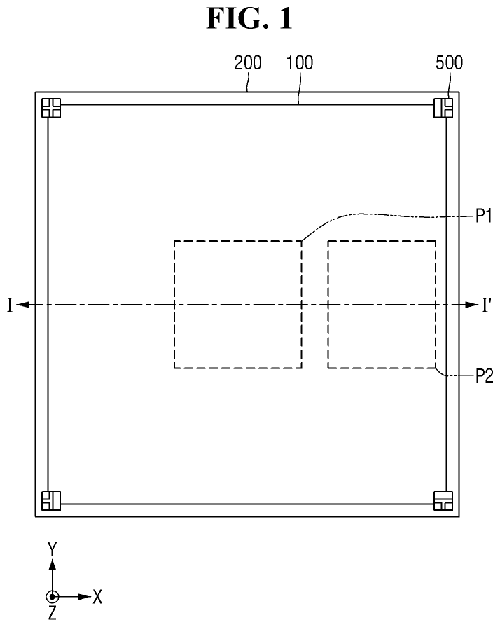

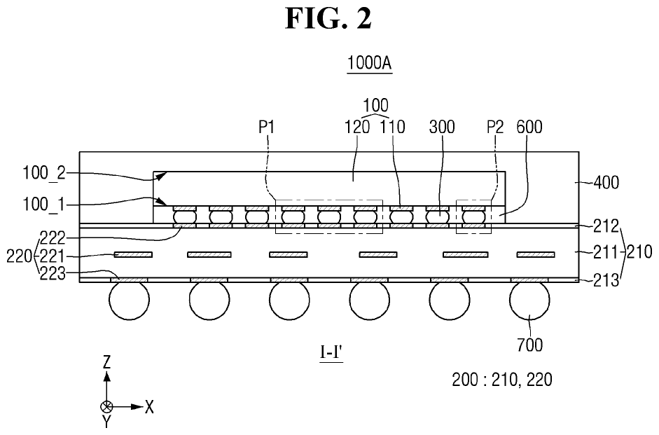

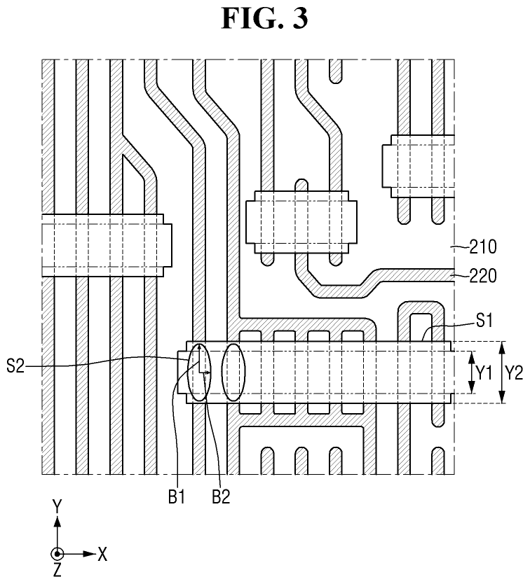

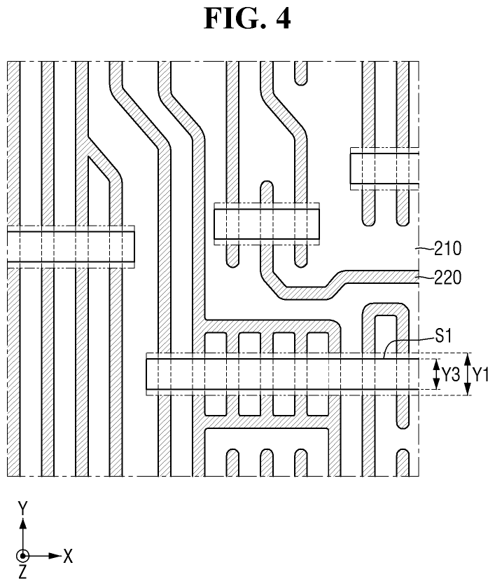

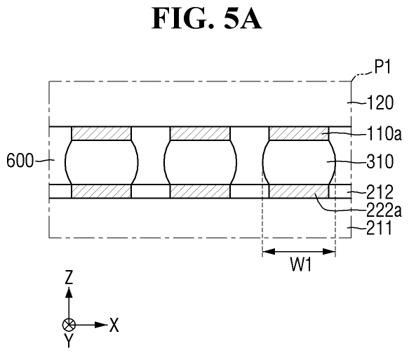

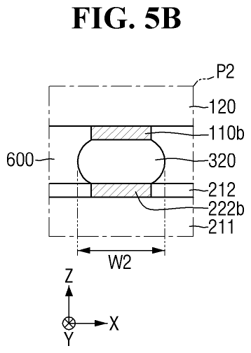

FIG. 1 is an exemplary layout view describing a semiconductor package according to some embodiments of the present disclosure. FIG. 2 is a sectional view taken along line I-I′ of FIG. 1. FIG. 3 is an enlarged view illustrating area P1 of FIG. 1. FIG. 4 is an enlarged view illustrating area P2 of FIG. 1. FIG. 5A is an enlarged view describing the area P1 of FIG. 2. FIG. 5B is an enlarged view illustrating the area P2 of FIG. 2.

Referring to FIGS. 1 and 2, a semiconductor package according to some embodiments may include a first semiconductor chip 100, a substrate 200, a bump structure 300, a mold layer 400, an alignment pattern 500, a non-conductive material layer 600, and a lower connection terminal 700.

The first semiconductor chip 100 may be disposed on a substrate 200 described below. The first semiconductor chip 100 may include an element layer 120 and a first semiconductor chip pad 110.

The first semiconductor chip 100 may include a first surface 100_1 and a second surface 100_2 opposite to the first surface 100_1 so that the first surface 100_1 and the second surface 100_2 face each other. The first semiconductor chip 100 may be mounted on the substrate 200 described below by a flip chip bonding scheme. The first surface 100_1 of the first semiconductor chip 100 may be an active surface facing the substrate 200 and may be electrically connected to the substrate 200.

Although not illustrated in detail, a passivation layer that exposes the first semiconductor chip pad 110 may be disposed on the first surface 100_1 of the first semiconductor chip 100. The first semiconductor chip pad 110 exposed by the passivation layer may electrically connect the substrate 200 to the first semiconductor chip 100.

The substrate 200 may include an insulating layer 210 and a wiring layer 220 in the insulating layer 210. The insulating layer 210 may include an insulating film 211 and first and second solder resist layers 212 and 213 on the insulating film 211. The wiring layer 220 may include first and second connection pads 222 and 223 in the first and second solder resist layers 212 and 213, and a wiring pad 221 in the insulating film 211.

One surface (i.e., an upper surface) of the substrate 200 may extend in a first direction Y and a second direction X. The first direction Y and the second direction X may be horizontal directions and may intersect one another. The first semiconductor chip 100 may be stacked on the upper surface of the substrate 200 in a third direction Z (i.e., a vertical direction) intersecting the first and second directions Y and X, respectively.

A plurality of lower connection terminals 700 described below may be disposed on the other surface (i.e., a lower surface) of the substrate 200. The wiring layer 220 of the substrate 100 may electrically connect the first semiconductor chip 100 to the lower connection terminal 700.

The substrate 200 may include, for example, a printed circuit board (PCB) or a ceramic substrate. However, embodiments are not limited thereto.

In an embodiment where the substrate 200 includes a printed circuit board, the insulating film 211 may include at least one material selected from a phenol resin, an epoxy resin and polyimide. For example, the insulating film 211 may include at least one material selected from an Ajinomoto build-up film (ABF), FR-4, tetrafunctional epoxy, polyphenylene ether, epoxy/polyphenylene oxide, bismaleimide triazine (BT), thermount, cyanate ester, polyimide and a liquid crystal polymer.

The first solder resist layer 212 and the second solder resist layer 213 may be disposed on upper and lower parts of the insulating film 211, respectively. Each of the first solder resist layer 212 and the second solder resist layer 213 may include, for example, a photosensitive insulating material (PID), but embodiments are not limited thereto.

The first solder resist layer 212 may be disposed on one surface of the insulating film 211. The first solder resist layer 212 may include a first open area P1 disposed adjacent to a central part of the first semiconductor chip 100 and a second open area P2 disposed adjacent to a peripheral part of the first semiconductor chip 100. Referring to FIG. 1, when viewed in a plan view, the second open area P2 may be disposed in a peripheral part of the first open area P1.

At least a part of the first connection pad 222 disposed on the first open area P1 may be exposed without being covered by the first solder resist layer 212. At least a part of the first connection pad 222 disposed on the second open area P2 may be exposed without being covered by the first solder resist layer 212. The exposed first connection pad 222 may electrically connect the wiring layer 220 to the first semiconductor chip 100.

The second solder resist layer 213 may be disposed on the other or lower surface of the insulating film 211. The second connection pad 223 may be exposed without being covered by the second solder resist layer 213. The exposed second connection pad 223 may be directly connected to the lower connection terminal 700.

The wiring layer 220 may include multiple layers. Although not specifically illustrated, the wiring layer 220 may further include a plurality of vias configured to electrically connect the first connection pad 222 and the second connection pad 223 to an inside.

The wiring layer 220 may include, for example, a conductive material. For example, the wiring layer 220 may include at least one metal or metal alloy selected from the group of or from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

A bump structure 300 may be disposed between the substrate 200 and the first semiconductor chip 100 to connect the substrate 200 and the first semiconductor chip 100. The bump structure 300 may be disposed between the first connection pad 222 and the first semiconductor chip pad 110 and be in contact with the first connection pad 222 and the first semiconductor chip pad 110, respectively. For example, the bump structure 300 may be used to bond the substrate 200 to the first semiconductor chip 100 in a thermal compression bonding process for bonding the substrate 200 to the first semiconductor chip 100.

Referring to FIGS. 5A and 5B, the bump structure 300 may include a first solder bump 310 disposed in the first open area P1 and a second solder bump 320 disposed in the second open area P2. The first connection pad 222 may include a first_first connection pad 222a disposed on an opening S1 (in FIG. 3) of the first open area P1 and a first_second connection pad 222b disposed on the opening S1 (in FIG. 4) of the second open area P2.

The first semiconductor chip pad 110 may include a first_first semiconductor chip pad 110a disposed on the first surface 100_1 of the first semiconductor chip 100 in the first open area P1, and a first_second semiconductor chip pad 110b disposed on the first surface 100_1 of the first semiconductor chip 100 in the second open area P2.

The first_first semiconductor chip pad 110a may be disposed on the first surface 100_1 of the first semiconductor chip 100 to correspond to the first_first connection pad 222a. The first_second semiconductor chip pad 110b may be disposed on the first surface 100_1 of the first semiconductor chip 100 to correspond to the first_second connection pad 222b.

Referring to FIG. 5A, the first solder bump 310 may be disposed between the first_first connection pad 222a and the first_first semiconductor chip pad 110a. Referring to FIG. 5B, the second solder bump 320 may be disposed between the first_second connection pad 222b and the first_second semiconductor chip pad 110b.

The first_first semiconductor chip pad 110a and the first_second semiconductor chip pad 110b may have a pillar shape such as a cylindrical pillar shape, but embodiments are not limited thereto. The first_first semiconductor chip pad 110a and the first_second semiconductor chip pad 110b may include, for example, copper (Cu), a copper alloy, nickel (Ni), palladium (Pd), platinum (Pt), gold (Au), cobalt (Co), and a combination thereof, but the present disclosure is not limited thereto.

The first solder bump 310 and the second solder bump 320 may be, for example, spherical or elliptical, but embodiments are not limited thereto. The first solder bump 310 and the second solder bump 320 may include, for example, tin (Sn), indium (In), bismuth (Bi), antimony (Sb), copper (Cu), silver (Ag), zinc (Zn), lead (Pb), and a combination thereof, but embodiments not limited thereto.

The mold layer 400 may be formed on the substrate 200. The mold layer 400 may be formed on the substrate 200 and may be disposed around or to surround the first semiconductor chip 100. Accordingly, the mold layer 400 may cover and protect the first semiconductor chip 100 and the substrate 200.

The mold layer 400 may include, for example, an insulating polymer material such as epoxy molding compound (EMC). The mold layer 400 may include a thermosetting resin such as an epoxy resin, a thermoplastic resin such as polyimide, or a resin including a reinforcing material such as a filler, and may include, for example, an ABF resin, an FR-4 and a BT resin.

The filler may include at least one of or at least one selected from the group consisting of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃). However, the material of the filler is not limited thereto, and may include a metal material and/or an organic material.

When viewed in a plan view, a plurality of alignment patterns 500 may be disposed in edge areas of the first semiconductor chip 100. The plurality of alignment patterns 500 may have different shapes. The alignment pattern 500 may be used to align a position of the first semiconductor chip 100.

A non-conductive material layer 600 may be interposed between the first semiconductor chip 100 and the substrate 200. The non-conductive material layer 600 may fill or at least partially fill the space between the bump structures 300. The non-conductive material layer 600 may protect the first semiconductor chip 100 and the substrate 200 and attach the first semiconductor chip 100 and the substrate 200 disposed adjacent to each other. The non-conductive material layer 600 may include, for example, a non-conductive film (NCF) or a non-conductive paste (NCP), but embodiments are not limited thereto.

The lower connection terminal 700 may electrically connect the substrate 200 to an external device. Accordingly, the lower connection terminal 700 may provide an electrical signal to the substrate 200 or provide an electrical signal provided from the substrate 200 to the external device.

The lower connection terminal 700 may be, for example, spherical or elliptical, but embodiments are not limited thereto. The lower connection terminal 700 may include, for example, at least one of tin (Sn), indium (In), lead (Pb), zinc (Zn), nickel (Ni), gold (Au), silver (Ag), copper (Cu), antimony (Sb), bismuth (Bi), and a combination thereof, but embodiments are not limited thereto.

Referring to FIG. 3, a length Y2 of the opening S1 of the first open area P1 along the first direction Y according to some embodiments may be increased by a predetermined length as compared to a length Y1 of the opening S1 of the conventional first open area P1 along the first direction Y. For instance, the length Y2 of the opening S1 of the first open area P1 along the first direction Y according to some embodiments may be 1.1 times or more of the length Y1 of the opening S1 of the conventional first open area P1 along the first direction Y.

In other words, as compared to the length Y1 of the opening S1 of the conventional first open area P1 along the first direction Y1, the length Y2 of the opening S1 of the first open area P1 along the first direction Y1 according to some embodiments may protrude by approximately 10%. However, embodiments are not limited thereto.

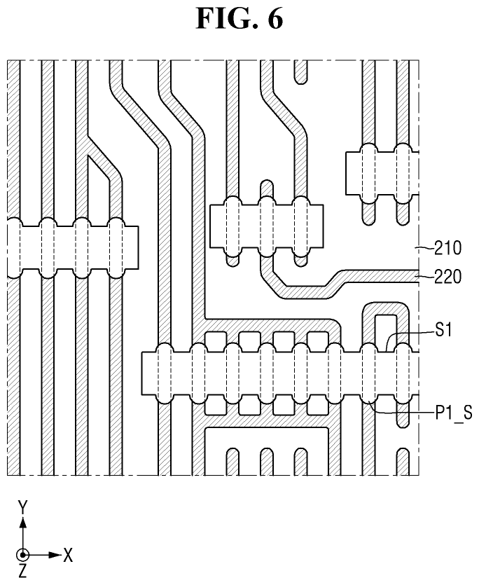

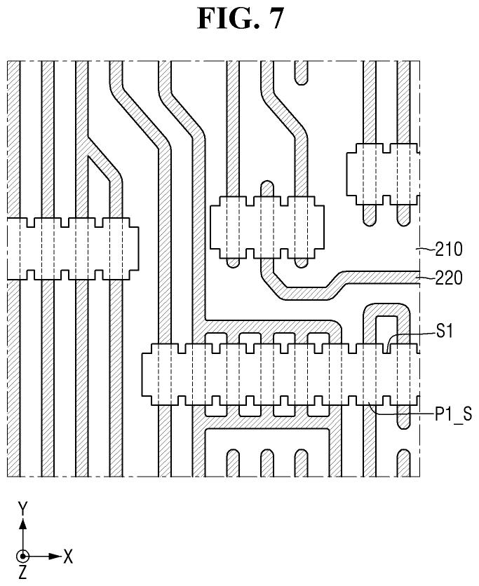

Unlike the embodiments illustrated in FIGS. 6 to 7 described below, the opening S1 of the first open part P1 further protruding in the first direction Y may have a shape extending in the second direction X.

Referring to FIG. 4, as compared to the length Y1 of the opening S1 of the conventional second open area P2 along the first direction Y, a length Y3 of the opening S1 of the second open area P2 along the first direction Y according to some embodiments may be reduced by a predetermined length. For instance, the length Y3 of the opening S1 of the second open area P2 along the first direction Y according to some embodiments may be 0.9 times or less of the length Y1 of the opening S1 of the conventional second open area P2 along the first direction Y.

In other words, as compared to the length Y1 of the opening S1 of the conventional second open area P2 along the first direction Y1, the length Y3 of the opening S1 of the second open area P2 along the first direction Y1 according to some embodiments may be reduced by approximately 10%. However, embodiments are not limited thereto.

Referring to FIGS. 3 and 4, the length Y2 of the opening S1 of the first open area P1 along the first direction Y may exceed the length Y3 of the opening S1 of the second open area P2 in the first direction Y.

In other words, the ratio of the length Y2 of the opening S1 of the first open area P1 along the first direction Y to the length X of the opening S1 of the first open area P1 along the second direction X may be larger than the ratio of the length Y3 of the opening S1 of the second open area P2 along the first direction Y to the length of the opening S1 of the second open area P2 along the second direction X.

Furthermore, unlike the length along the first direction Y, the length of the opening S1 of the first open area P1 along the second direction X may be substantially the same as or similar to that of the opening S1 of the second open area P2 along the second direction X.

Referring to an arrangement area S2 of the solder bump of FIG. 3, a length B1 of the first solder bump 310 of the first open area P1 along the first direction Y may exceed a length B2 of the first solder bump 310 of the first open area P1 along the second direction X.

In the first open area P1, since the opening area of the solder resist layer is increased in the first direction Y as described above, the shape of the first solder bump 310 may also be increased in the first direction Y. Accordingly, the shape of the first solder bump 310 along the second direction X may be relatively reduced compared to the length of the first solder bump 310 along the first direction Y. That is, the first solder bump 310 may have a length along the second direction X that is smaller than a length along the first direction Y. Accordingly, in an embodiment, a distance between solder bumps 310 may be increased in the second direction X.

As a result, according to embodiments, a short in the second direction X between the solder bumps 310 adjacent to a central part of the semiconductor chip 100 may be prevented. In other words, with the increase in a solder resist opening area in the first direction Y, it is possible to control the excessive diffusing phenomenon of the solder bumps 310 adjacent to the central part of the semiconductor chip 100 in the second direction X.

Although not illustrated in detail, unlike FIG. 3, FIG. 4 illustrates that the length of the second solder bump 320 of the second open area P2 along the first direction Y may be smaller than that of the second solder bump 320 of the second open area P2 in the second direction X.

In the second open area P2, since the opening area of the solder resist layer is reduced in the first direction Y as described above, the shape of the second solder bump 320 may also be reduced in the first direction Y. Accordingly, the shape of the second solder bump 320 along the second direction X may be relatively more increased than the length of the second solder bump 320 along the first direction Y. That is, a length of the second solder bump 320 along a second direction X may be greater than a length of the second solder bump 320 along the first direction Y.

Accordingly, in an embodiment, it may be possible to prevent the solder bumps 320 adjacent to the peripheral part of the semiconductor chip 100 from being non-wet in the second direction X. In other words, with the reduction of the solder resist opening area in the first direction Y, it may be possible to induce stable soldering of the solder bumps 320 adjacent to the peripheral part of the semiconductor chip.

In other words, referring to FIGS. 5A and 5B together, a width W1 of the first solder bump 310 of the first open area P1 in the second direction X may be smaller than a width W2 of the second solder bump 320 of the second open area P2 in the second direction X.

The openings S1 of the first and second open areas P1 and P2 illustrated in FIGS. 3 and 4 may be formed by using masks disposed on the substrate 200 corresponding to each of the openings.

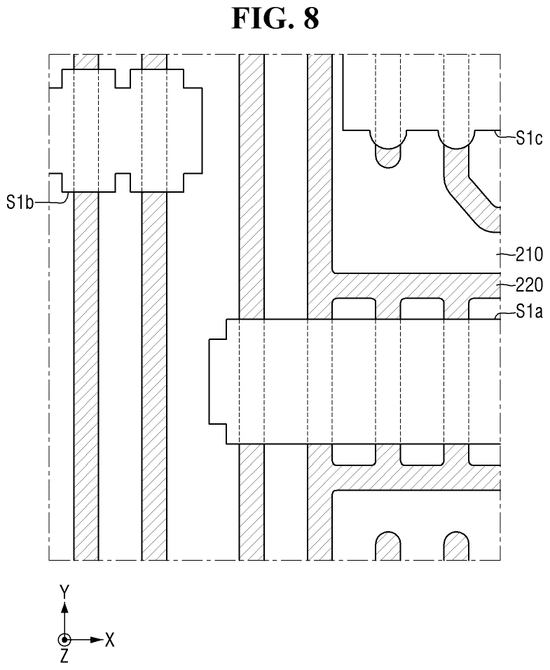

FIG. 6 is a view illustrating the semiconductor package according to some embodiments and corresponding to FIG. 3. FIG. 7 is a view illustrating the semiconductor package according to some embodiments and corresponding to FIG. 3. FIG. 8 is a view illustrating the semiconductor package according to some embodiments and corresponding to FIG. 3. For convenience of explanation, the description of content overlapping the content described with reference to FIGS. 1 to 5 may be omitted.

Referring to FIG. 6, the opening S1 of the first open area P1 may include a plurality of spaced portions P1_S spaced apart from each other in the second direction X. The plurality of spaced portions P1_S may include curved parts. The opening S1 of the first open area P1 may include a shape protruding in the first direction Y.

In an embodiment, the openings S1 of the first open area P1 may be spaced apart from each other in the second direction X in a shape corresponding to the wiring layer 220.

Referring to FIG. 7, the opening S1 of the first open area P1 may include the plurality of spaced portions P1_S spaced apart from each other in the second direction X. The plurality of spaced portions P1_S may include a rectangular shape. The opening S1 of the first open area P1 may include a shape protruding in the first direction Y.

In an embodiment, the openings S1 of the first open area P1 may be spaced apart from each other in the second direction X in a shape corresponding to the wiring layer 220.

The opening S1 of the first open part P1 illustrated in FIGS. 6 and 7 may be formed by using masks spaced apart from each other on the substrate 200 to correspond to each of open areas.

With reference to FIG. 8, the shapes of first open areas P1a, P1b and P1c illustrated in FIGS. 3, 6 and 7 may be applied to one semiconductor package.

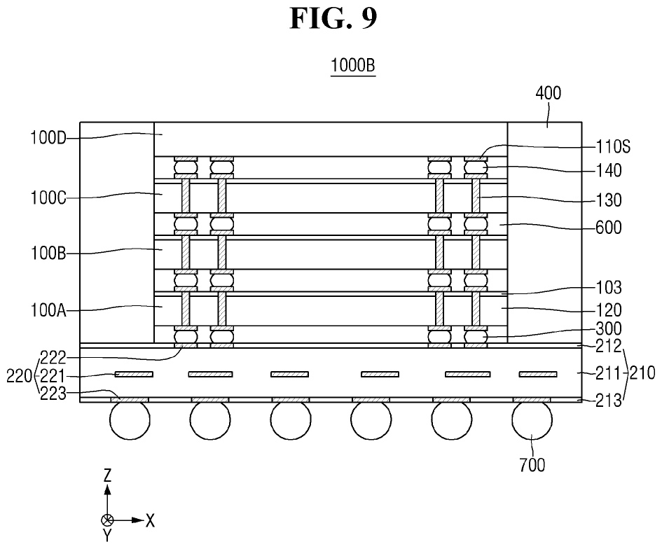

FIG. 9 is a sectional view illustrating the semiconductor package according to some embodiments. For convenience of explanation, a description of content overlapping the content described with reference to FIGS. 1 to 8 may be omitted.

Referring to FIG. 9, a semiconductor package 1000B according to some embodiments may include four semiconductor chips 100A, 100B, 100C and 100D stacked on the substrate 200 and a through via 130 penetrating the inside of the first to third semiconductor chips 100A, 100B and 100C. The first to fourth semiconductor chips 100A, 100B, 100C and 100D may be electrically connected to each other via the through via 130 and a second bump structure 140.

Although FIG. 9 illustrates that the first to fourth semiconductor chips 100A, 100B, 100C and 100D are stacked on the substrate 200, the number of semiconductor chips stacked on the substrate 200 is not limited to four. For instance, in various embodiments, two or three, or five or more semiconductor chips may be stacked on the substrate 200.

For example, the substrate 200 may be substantially similar or identical to the substrate 200 of the semiconductor package 1000A of FIG. 2. Although this is not illustrated in detail, the substrate 200 may include one or more through vias.

The through via 130 of each of the first to third semiconductor chips 100A, 100B and 100C may penetrate a protective layer 103 and the element layer 120. The through via 130 may be connected to connection pads 110S disposed in upper and lower parts thereof. The through via 130 penetrating the first semiconductor chip 100A may be connected to the connection pad 110S and be electrically connected to the first bump structure 300. The through via 130 penetrating each of the second and third semiconductor chips 100B and 100C may be connected to the connection pads 110S and be electrically connected to the second bump structure 140.

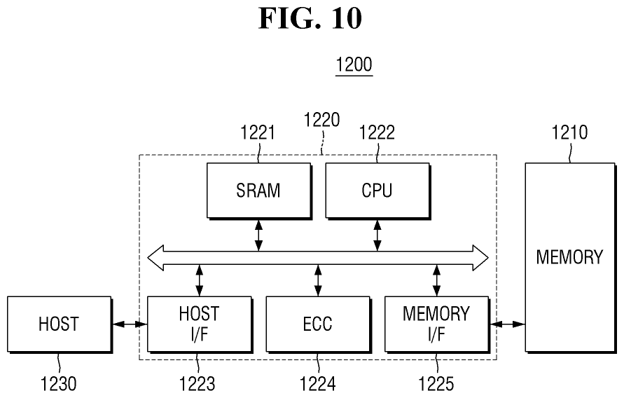

FIG. 10 is a block diagram illustrating a memory card including the semiconductor package according to some embodiments.

Referring to FIG. 10, the semiconductor packages 1000A and 1000B according to embodiments of the present disclosure may be applied to a memory card 1200.

The memory card 1200 may include a memory controller 1220 configured to control data exchange between a host 1230 and a memory 1210. An SRAM 1221 may be used as an operation memory of a central processing device 1222. A host interface 1223 may include a data exchange protocol of the host 1230 connected to the memory card 1200. An error correction code 1224 may detect and correct errors included in data read from the memory 1210. A memory interface 1225 may interface with the memory 1210. The central processing device 1222 may perform an overall control operation for exchanging data of the memory controller 1220.

For instance, at least one of the memory 1210 and the central processing device 1222 may include at least one of the semiconductor packages 1000A and 1000B according to some embodiments.

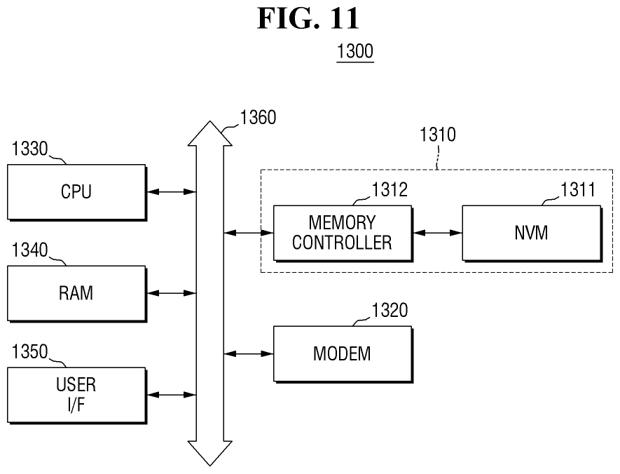

FIG. 11 is a block diagram illustrating an information processing system using the semiconductor package according to some embodiments.

Referring to FIG. 11, the semiconductor packages 1000A and 1000B according to some embodiments may be applied to an information processing system 1300.

The information processing system 1300 may include a mobile device or a computer. The information processing system 1300 may include a memory system 1310 electrically connected to a system bus 1360, a modem 1320, a central processing device 1330, a RAM 1340, and a user interface 1350. The memory system 1310 includes a memory 1311 and a memory controller 1312, and may be configured in substantially the same way as the memory card 1200 of FIG. 10. In addition, at least one of the central processing device 1330 and the RAM 1340 may include at least one of the semiconductor packages 1000A and 1000B according to some embodiments.

Data processed by the central processing device 1330 or data input from the outside may be stored in the memory system 1310. The information processing system 1300 may be provided as a memory card, a semiconductor disk device (i.e., a solid state disk), a camera image processor (i.e., a camera image sensor), and other application chipsets. For instance, the memory system 1310 may be made up of a semiconductor disk device (SSD), and the information processing system 1300 may stably and reliably store a large amount of data in the memory system 1310.

While aspects of example embodiments have been particularly shown and described, it will be understood that various changes in form and details may be made therein without departing from the spirit and scope of the following claims.

What is claimed is:

1. A semiconductor package, comprising:
a substrate extending in first direction and a second direction intersecting the first direction and comprising a solder resist layer having an open area thereon;
a semiconductor chip on the substrate in a third direction, the third direction intersecting the first direction and the second direction, a first surface of the semiconductor chip facing the substrate; and
a bump structure in contact with a first connection pad on the open area and a second connection pad on the first surface of the semiconductor chip, and configured to connect the substrate to the semiconductor chip,
wherein the open area comprises a first area and a second area disposed in a peripheral part of the first area, and
wherein a length of the first area in the first direction is greater than a length of the second area in the first direction.

2. The semiconductor package of claim 1, wherein a ratio of the length of the first area in the first direction to a length of the first area in the second direction is larger than a ratio of the length of the second area in the first direction to a length of the second area in the second direction.

3. The semiconductor package of claim 1, wherein a width of the bump structure in the first area in the second direction is smaller than a width of the bump structure in the second area in the second direction.

4. The semiconductor package of claim 1, wherein a length of the first area in the second direction is substantially the same as a length of the second area in the second direction.

5. The semiconductor package of claim 1, wherein a length of the bump structure in the first area in the first direction is greater than a length of the bump structure in the first area in the second direction.

6. The semiconductor package of claim 1, wherein the open area comprises a plurality of spaced portions spaced apart from each other in the second direction.

7. The semiconductor package of claim 6, wherein each of the plurality of spaced portions comprises curved parts.

8. The semiconductor package of claim 1, further comprising a plurality of alignment patterns disposed adjacent to edge areas of the semiconductor chip, when viewed in a plan view.

9. The semiconductor package of claim 8, wherein the plurality of alignment patterns have different shapes.

10. The semiconductor package of claim 1, further comprising a non-conductive material layer between the substrate and the semiconductor chip.

11. The semiconductor package of claim 1, further comprising a plurality of semiconductor chips electrically connected via a through via and a connection structure on the semiconductor chip.

12. A semiconductor package, comprising:
a semiconductor chip;
a substrate on a lower part of the semiconductor chip and extending in a first direction and a second direction intersecting the first direction, and comprising a solder resist layer having a first open area in a central part of the semiconductor chip and a second open area in a peripheral part of the semiconductor chip, when viewed in a plan view; and
a bump structure connecting the substrate to the semiconductor chip,
wherein the bump structure comprises:
a first solder bump in contact with a first connection pad disposed on the first open area and a second connection pad disposed on a first surface of the semiconductor chip; and
a second solder bump in contact with a third connection pad disposed on the second open area and a fourth connection pad disposed on the first surface of the semiconductor chip,
wherein a length of the first open area in the first direction is greater than a length of the second open area in the first direction, and
wherein a width of the first solder bump in the first open area in the second direction is smaller than a width of the second solder bump in the second open area in the second direction.

13. The semiconductor package of claim 12, wherein a ratio of the length of the first open area in the first direction to a length of the first open area in the second direction is larger than a ratio of a length of the second open area in the first direction to a length of the second open area in the second direction.

14. The semiconductor package of claim 12, wherein a length of the first solder bump in the first open area in the first direction is greater than a length of the first solder bump in the first open area in the second direction.

15. The semiconductor package of claim 12, wherein a length of the second solder bump in the second open area in the first direction is smaller than a length of the second solder bump in the second open area in the second direction.

16. The semiconductor package of claim 12, wherein the first open area comprises a curved part.

17. The semiconductor package of claim 12, further comprising a plurality of alignment patterns disposed adjacent to edge areas of the semiconductor chip, when viewed in a plan view,
wherein the plurality of alignment patterns have different shapes.

18. A semiconductor package, comprising:
a substrate extending in a first direction and a second direction intersecting the first direction and comprising a solder resist layer having an open area thereon;
a first semiconductor chip disposed on the substrate and stacked vertically so that the substrate and a first surface of the first semiconductor chip face each other;
an alignment pattern disposed adjacent to an edge area of the first semiconductor chip;
a non-conductive material layer between the substrate and the first semiconductor chip; and
a first bump structure disposed between a first connection pad on the open area and a second connection pad on the first surface of the first semiconductor chip and connecting the substrate to the first semiconductor chip,
wherein the open area comprises a first area and a second area adjacent to a peripheral part of the first area, when viewed in a plan view, and
wherein a length of the first area in the first direction is greater than a length of the second area in the first direction.

19. The semiconductor package of claim 18, wherein a width of the first bump structure in the first area in the second direction is smaller than a length of the first bump structure in the second area in the second direction.

20. The semiconductor package of claim 18, further comprising a plurality of semiconductor chips electrically connected via a through via and a second bump structure on the first semiconductor chip.
